(19) United States
(12) Patent Application Publication
(10) Pub. No.: US 2007/0107845 A1
(43) Pub. Date: May 17, 2007

(54) SEMICONDUCTOR PROCESSING SYSTEM

(76) Inventors: Shigeru Ishizawa, Nirasaki-shi (JP); Hiroaki Saeki, Nirasaki-shi (JP); Yoshimitsu Tamura, Tokyo (JP); Shigetoshi Hosaka, Nirasaki-shi (JP); Masahide Itoh, Nirasaki-shi (JP); Kazushi Tahara, Nirasaki-shi (JP); Yasushi Kodashima, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/623,573

(22) Filed: Jan. 16, 2007

Related U.S. Application Data
(63) Continuation of application No. 10/486,511, filed on Feb. 12, 2004.

(30) Foreign Application Priority Data
Aug. 14, 2001 (JP) 2001-246088

(51) Int. Cl. C23F 1/00; H01L 21/306; C23C 16/00

(52) U.S. Cl. 156/345.32; 118/719; 156/345.31

(57) ABSTRACT

A semiconductor processing system includes an intermediate structure disposed between an atmospheric pressure entrance transfer chamber and a vacuum common transfer chamber. The intermediate structure includes a transfer passage for a target substrate to pass therein. The transfer passage includes a first buffer chamber a middle transfer chamber and a second buffer chamber detachably connected. An additional processing apparatus is detachably connected to the middle transfer chamber. The intermediate structure is selectively arranged in first or second state. In the first state, the additional processing apparatus performs a vacuum process, while the first buffer chamber is a load-lock chamber. In the second state, the additional processing apparatus performs an atmospheric pressure process, while the second buffer chamber is a load-lock chamber.

### CROSS-REFERENCE TO RELATED APPLICATIONS

This application is a Continuation of and claims the benefit of priority under 35 U.S.C. §120 from U.S. Ser. No. 10/486,511, filed on Feb. 12, 2004, which is a national stage of international filing PCT/JP02/07817 filed Jul. 31, 2002. This application also claims the benefit of priority under 35 U.S.C. §119 from Japanese Patent Application No. 2001-246088, filed Aug. 14, 2001, the entire contents of each which is incorporated herein by reference.

### TECHNICAL FIELD

The present invention relates to a semiconductor processing system having a plurality of vacuum processing apparatuses for performing predetermined processes on a target substrate, such as a semi-conductor wafer. The term “semiconductor process” used herein includes various kinds of processes which are performed to manufacture a semiconductor device or a structure having wiring layers, electrodes, and the like to be connected to a semiconductor device, on a target substrate, such as a semiconductor wafer or an LCD substrate, by forming semiconductor layers, insulating layers, and conductive layers in predetermined patterns on the target substrate.

### BACKGROUND ART

In the process of manufacturing semiconductor integrated circuits, a wafer is subjected to various processes, such as film-formation, etching, oxidation, and diffusion. Owing to the demands of increased miniaturization and integration of semiconductor integrated circuits, the throughput and yield involving these processes need to be increased. In light of this, there is a semiconductor processing system of the so-called cluster tool type, which has a plurality of process chambers for performing the same process, or a plurality of process chambers for performing different processes, connected to a common transfer chamber. With a system of this type, various steps can be performed in series, without exposing a wafer to air. For example, Jpn. Pat. Appln. KOKAI Publication Nos. 2000-208589 and 2000-299367 disclose a semiconductor processing system of the cluster tool type. The assignee of the present invention also filed Jpn. Pat. Appln. No. 2001-060968 disclosing an improved semiconductor processing system of the cluster tool type.

FIG. 14 is a structural view schematically showing a conventional processing system of the cluster tool type. As shown in FIG. 14, the processing system 2 includes three processing apparatuses 4A, 4B, and-4C, a first transfer chamber 6, two load-lock chambers 8A and 8B provided with a pre-heating mechanism or cooling mechanism, a second transfer chamber 10, and two cassette chambers 12A and 12B. The three processing apparatuses 4A to 4C are connected to the first transfer chamber 6 in common. The two load-lock chambers 8A and 8B are disposed in parallel with each other between the first and second transfer chambers 6 and 10. The two cassette chambers 12A and 12B are connected to the second transfer chamber 10. A gate valve G to be airtightly opened/closed is interposed between each two of the chambers.

The first and second transfer chambers 6 and 10 are respectively provided with first and second transfer arm devices 14 and 16 disposed therein, each of which is formed of an articulated structure that can extend, contract, and rotate. Each of the arm devices 14 and 16 is arranged to hold a semiconductor wafer W to transfer it. The second transfer chamber 10 is provided with an alignment mechanism 22 disposed therein, which is formed of a rotary table 18 and an optical sensor 20. The alignment mechanism 22 is arranged to rotate a wafer W transferred from the cassette chamber 12A or 12B, and detect its orientation flat or notch to perform alignment thereon.

When a semiconductor wafer W is processed, an unprocessed semiconductor wafer W is first taken out of a cassette C placed in one of the cassette chambers, e.g., a cassette chamber 12A, by the second transfer arm device 16 disposed in the second transfer chamber 10, which has been kept at atmospheric pressure with an N2 atmosphere. Then, the wafer W is transferred by the arm device 16 and placed on the rotary table 18 of the alignment mechanism 22 disposed in the second transfer chamber 10. The arm device 16 is kept stationary on standby while the rotary table 18 rotates to perform alignment. The time period necessary for this alignment operation is, e.g., about 10 to 20 seconds.

After the alignment operation, the aligned wafer W is held again by the arm device 16, which has been on standby, and transferred into one of the load-lock chambers, e.g., the chamber 8A. The wafer is pre-heated in the load-lock chamber 8A, as needed, and, at the same time, the interior of the load-lock chamber 8A is vacuum-exhausted to a predetermined pressure. The time period necessary for performing this pre-heating or vacuum-exhaust is, e.g., about 30 to 40 seconds.

After the pre-heating operation, the gate valve G between the load-lock chamber 8A and the first transfer chamber 6, which is set at vacuum in advance, is opened to make them communicate with each other. Then, the pre-heated wafer W is held by the first transfer arm device 14 and transferred into a predetermined processing apparatus, e.g., 4A. Then, a predetermined process, such as a film-formation process of a metal film, insulating film, or the like, is performed in the processing apparatus 4A. The time period necessary for performing this process is, e.g., about 60 to 90 seconds.

The processed semiconductor wafer W is transferred, through a route reverse to the route described above, to, e.g., the original cassette C placed in the cassette chamber 12A. In this route to return the processed wafer W, the other load-lock chamber 8B is used, for example, and the wafer W is transferred after it is cooled to a predetermined temperature. The time period necessary for performing this cooling and returning to atmospheric pressure is about 30 to 40 seconds. Before the processed wafer W is transferred into the cassette C, alignment may be performed by the alignment mechanism 22, as needed.

As semiconductor wafer processes progress in level′ of miniaturization and integration, decrease in film thickness, and increase in the number of layers, integrated circuits are increasingly required to have diversified functions. As a result, manufacture of semiconductor integrated circuits tends to shift from small item large volume production to large item small volume production.

In the processing system of the cluster tool type shown in FIG. 14, the processing apparatuses 4A to 4C connected by the gate valves G can be detached and replaced with other processing apparatuses to perform other vacuum processes, as needed. However, the processing system may be required to be used in different ways, due to the recent trend described above. For example, there may be a case where a processing apparatus for performing another vacuum process needs to be added to the processing system, a processing apparatus for performing a normal pressure process needs to be added to the processing system, or a processing apparatus for performing a vacuum process needs to be replaced with a processing apparatus for performing a normal pressure process. However, the processing system shown in FIG. 14 has fixed structures, except for the three vacuum processing apparatuses 4A to 4, and thus is very difficult to comply with the request described above.

One solution is to provide two apparatuses: one processing apparatus for performing a vacuum atmosphere process, and another for performing a normal pressure atmosphere process, both of which are connected to the first transfer chamber 6. In this case, however, it takes a long time to perform pressure adjustment between chambers when wafers are transferred, thereby inevitably bringing about a substantial decrease in throughput, to an unpractical level.

### DISCLOSURE OF INVENTION

Accordingly, an object of the present invention is to provide a semiconductor processing system that can easily incorporate either of additional processing apparatuses for performing a vacuum atmosphere process and an atmospheric pressure atmosphere process.

According to a first aspect of the present invention, there is provided a semiconductor processing system comprising:

an entrance transfer chamber with an atmospheric pressure atmosphere, which has a loading port for loading a target substrate into the semiconductor processing system;

a common transfer chamber with a vacuum atmosphere, which is connected to the entrance transfer chamber through an intermediate structure that forms a route for transferring the target substrate;

a plurality of vacuum processing apparatuses connected to the common transfer chamber, each of which is configured to perform a predetermined process on the target substrate within a vacuum atmosphere;

a transfer arm device disposed in the entrance transfer chamber and configured to transfer the target substrate between a portion outside the semiconductor processing system and the intermediate structure; and

a transfer arm device disposed in the common transfer chamber and configured to transfer the target substrate between the intermediate structure and the vacuum processing apparatuses,
wherein the intermediate structure comprises a transfer passage that connects the entrance transfer chamber and the common transfer chamber to allow the target substrate to pass therein, and includes a first buffer chamber, a middle transfer chamber, and a second buffer chamber connected in series in this order and detachable from each other, such that the first and second buffer chambers are detachably connected to the entrance transfer chamber and the common transfer chamber, respectively,

an additional processing apparatus detachably connected to the middle transfer chamber, and

a transfer arm device disposed in the middle transfer chamber and configured to transfer the target substrate between the first buffer chamber, the additional processing apparatus, and the second buffer chamber; and

the intermediate structure is selectively arranged to be in one of first and second states, the first state being a state where the additional processing apparatus is set to perform a predetermined process on the target substrate within a vacuum atmosphere, while the first buffer chamber is set to be a load-lock chamber for adjusting pressure between atmospheric pressure and vacuum, and the second state being a state where the additional processing apparatus is set to perform a predetermined process on the target substrate within an atmospheric pressure atmosphere, while the second buffer chamber is set to be a load-lock chamber for adjusting pressure between atmospheric pressure and vacuum.

According to a second aspect of the present invention, there is provided a semiconductor processing system comprising:

an entrance transfer chamber with an atmospheric pressure atmosphere, which has a loading port for loading a target substrate into the semiconductor processing system;

a common transfer chamber with a vacuum atmosphere, which is connected to the entrance transfer chamber through first and second intermediate structures that form routes parallel with each other for transferring the target substrate;

a plurality of vacuum processing apparatuses connected to the common transfer chamber, each of which is configured to perform a predetermined process on the target substrate within a vacuum atmosphere;

a transfer arm device disposed in the entrance transfer chamber and configured to transfer the target substrate between a portion outside the semiconductor processing system and the first and second intermediate structures; and

a transfer arm device disposed in the common transfer chamber and configured to transfer the target substrate between the first and second intermediate structures and the vacuum processing apparatuses,

wherein each of the first and second intermediate structures comprises

a transfer passage that connects the entrance transfer chamber and the common transfer chamber to allow the target substrate to pass therein, and includes a first buffer chamber, a middle transfer chamber, and a second buffer chamber connected in series in this order and detachable from each other, such that the first and second buffer chambers are detachably connected to the entrance transfer chamber and the common transfer chamber, respectively,

an additional processing apparatus detachably connected to the middle transfer chamber, and

a transfer arm device disposed in the middle transfer chamber and configured to transfer the target substrate between the first buffer chamber, the additional processing apparatus, and the second buffer chamber.

### BRIEF DESCRIPTION OF DRAWINGS

FIG. 1 is a schematic plan view showing one state of a semiconductor processing system according to an embodiment of the present invention;

FIG. 2 is a plan view showing the processing system of FIG. 1 in detail;

FIG. 3 is an enlarged sectional view taken along line III-III in FIG. 2;

FIG. 4 is an enlarged perspective view showing a gate valve, used in the processing system of FIG. 1;

FIG. 5 is an enlarged perspective view showing a sleeve pipe having no valve function, used in the processing system of FIG. 1;

FIGS. 6A and 6B are enlarged sectional views showing a first buffer chamber, used in the processing system of FIG. 1;

FIG. 7 is a schematic plan view showing another state of the processing system of FIG. 1, obtained by changing some modules;

FIG. 8 is a plan view of the state of the processing system shown in FIG. 7;

FIG. 9 is an enlarged sectional view taken along line IX-IX in FIG. 8;

FIG. 10 is a schematic plan view showing still another state of the processing system of FIG. 1, obtained by changing some modules;

FIG. 11 is a schematic plan view showing a semiconductor processing system according to another embodiment of the present invention;

FIG. 12 is a schematic plan view showing a semiconductor processing system according to still another embodiment of the present invention;

FIG. 13 is a schematic plan view showing a semiconductor processing system according to still another embodiment of the present invention; and

FIG. 14 is a structural view schematically showing a conventional semiconductor processing system of the cluster tool type.

### BEST MODE FOR CARRYING OUT THE INVENTION

Embodiments of the present invention will be described hereinafter with reference to the accompanying drawings. In the following description, the constituent elements having substantially the same function and arrangement are denoted by the same reference numerals, and a repetitive description will be made only when necessary.

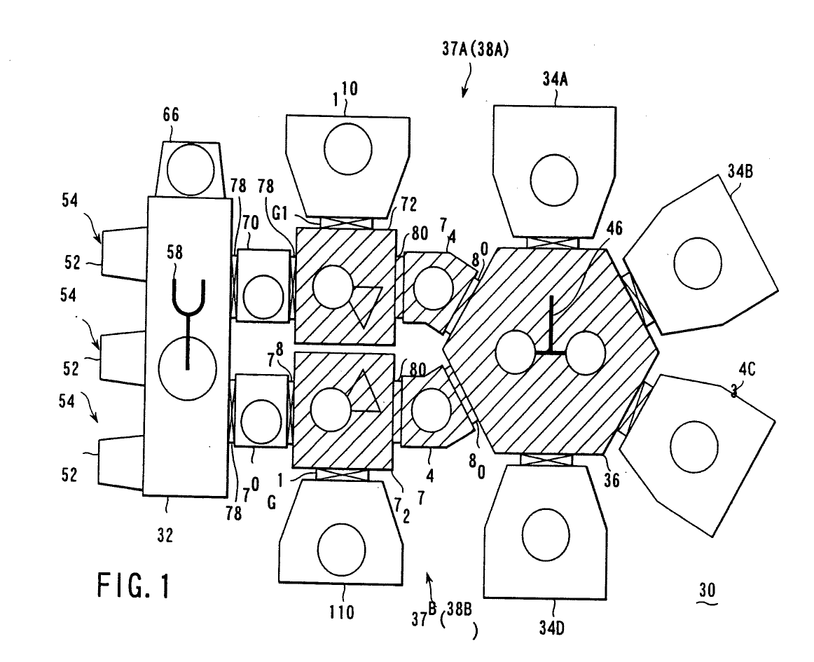

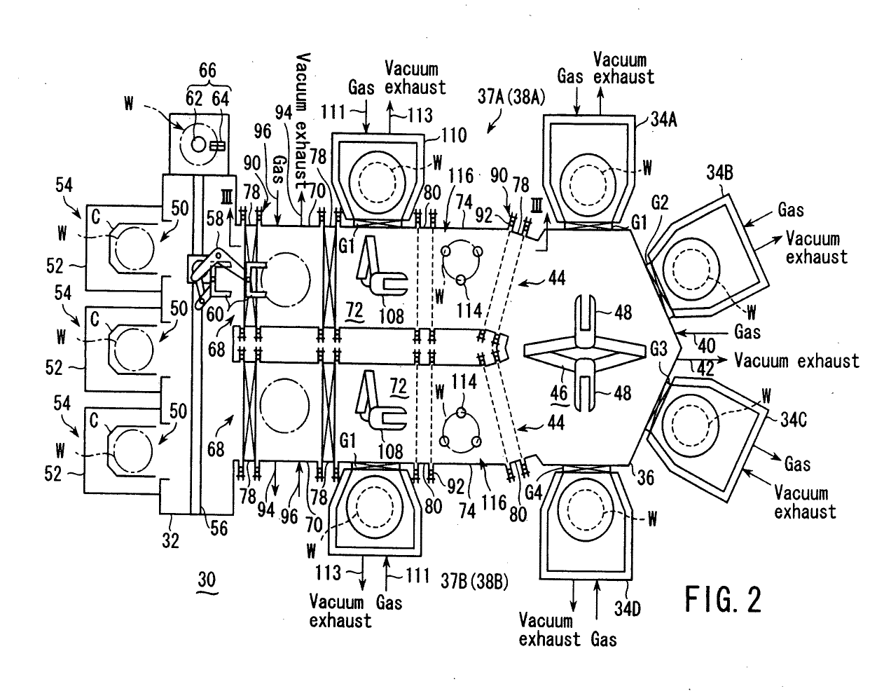

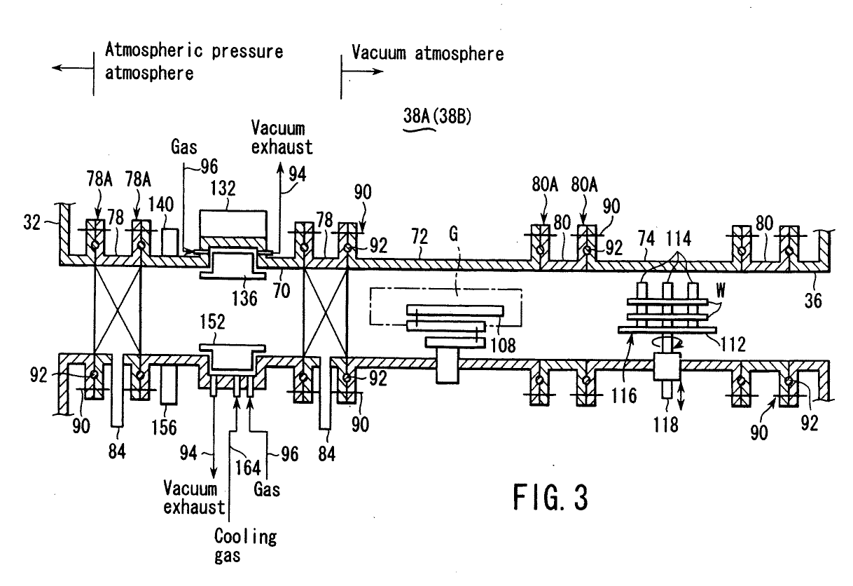

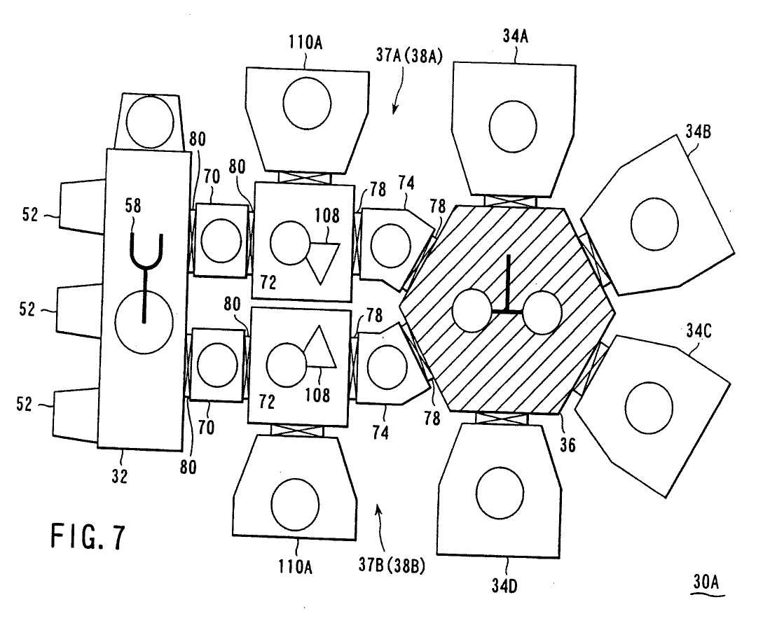

FIG. 1 is a schematic plan view showing one state of a semiconductor processing system according to an embodiment of the present invention. FIG. 2 is a plan view showing the processing system of FIG. 1 in detail. FIG. 3 is an enlarged sectional view taken along line III-III in FIG. 2. The shaded portions in FIG. 1 denote portions that are kept in continuous vacuum when the system operates. The shaded portions in the plan views shown in FIGS. 7, 10, 12, and 13 denote the same.

As shown in FIGS. 1 and 2, the processing system 30 includes an entrance transfer chamber 32 with an atmospheric pressure atmosphere, into which a target substrate, such as a semiconductor wafer W, is transferred. The processing system 30 also includes a common transfer chamber 36 with a vacuum atmosphere, to which a plurality of, e.g., four in this illustrated example, vacuum processing apparatuses 34A, 34B, 34C, and 34D are connected therearound. The entrance transfer chamber 32 and common transfer chamber 36 are connected to each other by a plurality of routes for transferring semiconductor wafers W, e.g., two parallel transfer passages 38A and 38B in this illustrated example. The transfer passages 38A and 38B are formed as parts of intermediate structures 37A and 37B, respectively, disposed between the entrance transfer chamber 32 and common transfer chamber 36.

The common transfer chamber 36 is formed of, e.g., an aluminum container having a hexagonal shape as a whole. A gas supply system 40 and a vacuum exhaust system 42 are connected to the common transfer chamber 36, so that it can be supplied with an inactive gas, such as N2 gas, and can be vacuum-exhausted.

Ports 44 for transferring wafers W therethrough are respectively formed in two sides of the common transfer chamber 36 adjacent to each other. A common transfer arm device 46, which can extend, contract, and rotate, is disposed at the center of the common transfer chamber 36. The arm device 46 has two picks 48, so that it can handle and transfer two wafers W at a time.

The four processing apparatuses 34A to 34D are connected to the other four sides of the common transfer chamber 36 through gate valves G1 to G4, respectively. Each of the processing apparatuses 34A to 34D can be supplied with a process gas and can be vacuum-exhausted, so that it can perform its own vacuum process within a vacuum atmosphere.

On the other hand, the entrance transfer chamber 32 is formed of, e.g., a stainless steel container having a long thin configuration. A plurality of, e.g., three in this illustrated example, openings 50 are formed in one long side of the entrance transfer chamber 32. A table 52 for placing a cassette container C thereon is disposed outside each of the openings 50 to constitute a loading port 54. The cassette container C may be of the open type or the closed type with an openable lid. In either case, the cassette container C is structured to store a plurality of, e.g., about 25, wafers W.

A guide rail 56 is disposed in the entrance transfer chamber 32 and extends in its longitudinal direction. An entrance transfer arm device 58 is arranged to be movable along the guide rail 56. The arm device 58 is formed of an articulated arm device that can extend, contract, and rotate. The arm device 58 has two picks 60, so that it can handle and transfer two wafers W at a time.

An orientor 66 including a rotary table 62 and an optical sensor 64 is disposed at one end of the entrance transfer chamber 32 in the longitudinal direction. The orientor 66 is arranged to detect the notch or orientation flat of a wafer W to perform alignment thereon.

Two opening ports 68 are formed in the other long side of the entrance transfer chamber 32. The two opening ports 68 are respectively connected to the transfer passages 38A and 38B of the intermediate structures 37A and 37B.

More specifically, each of the transfer passages 38A and 38B is formed of a first buffer chamber 70, a middle transfer chamber 72, and a second buffer chamber 74, connected in this order from the entrance transfer chamber 32 toward the common transfer chamber 36. Each of the chambers 70, 72, and 74 is formed of, e.g., an aluminum container defining a module. Each of two opposite ends of the container has an opening provided with a connection flange. The second buffer chamber 74 has a bent shape, so that its center faces the swivel center of the common transfer arm device 46 disposed in the common transfer chamber 36.

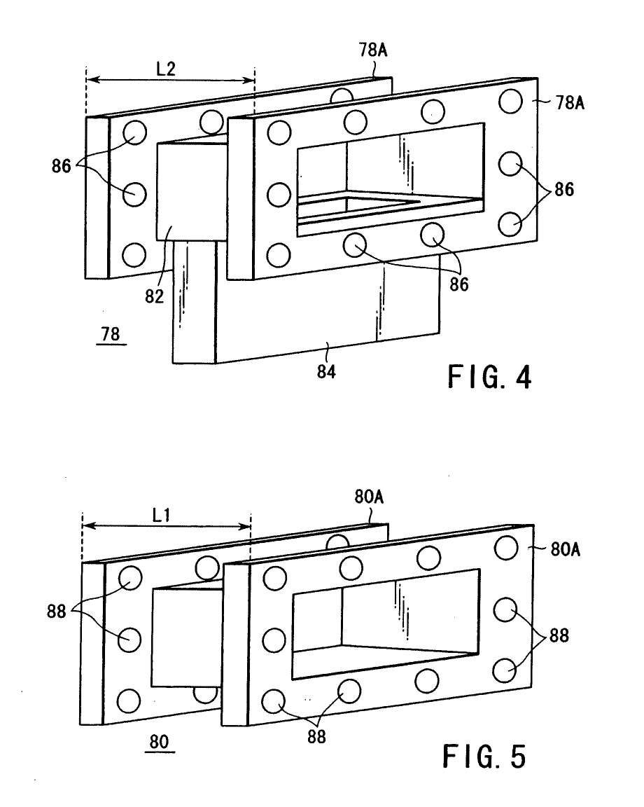

In the system shown in FIG. 1, the first buffer chamber 70 is set to be a load-lock chamber for adjusting pressure between atmospheric pressure and vacuum. The first buffer chamber 70 is connected to the adjacent chambers (the entrance transfer chamber 32 and middle transfer chamber 72) on both sides respectively through gate valves 78. FIG. 4 is an enlarged perspective view showing one gate valve 78. On the other hand, the second buffer chamber 74 is set to be a chamber having a vacuum atmosphere common to the middle transfer chamber 72 and common transfer chamber 36. The second buffer chamber 74 is connected to the adjacent chambers (the middle transfer chamber 72 and common transfer chamber 36) on both sides respectively through sleeve pipes 80 having no valve function. FIG. 5 is an enlarged perspective view showing one sleeve pipe 80.

As shown in FIG. 4, the gate valve 78 includes a hollow valve casing 82 that has a size to allow a wafer in a horizontal state to pass therethrough. The valve casing 82 is provided with flanges 78A respectively at two opposite sides, and screw holes 86 are formed almost equidistantly in each flange 78A. The valve casing 82 is also provided with a disc receiving portion 84 for receiving a valve disc, which extends on one side. The valve disc (not shown) moves between the disc receiving portion 84 and valve casing 82 to open/close the gate valve 78.

As shown in FIG. 5, the sleeve pipe 80 includes a hollow pipe that has a size to allow a wafer in a horizontal state to pass therethrough, as in the valve casing 82. The hollow pipe is provided with flanges 80A respectively at two opposite sides, and screw holes 88 are formed almost equidistantly in each flange 80A.

The entire width L1 of the sleeve pipe 80 and the entire width L2 of the gate valve 78 are preset to be the same, so that replacement is made easy. The flange 78A or 80A is tightened and fixed by a number of bolts 90 to the flange of the adjacent first buffer chamber 70, middle transfer chamber 72, or second buffer chamber 74. A sealing member 92, such as an O-ring, is interposed between the flanges to form an airtight connection state. The chambers 70, 72, and 74, gate valves 78, and sleeve pipes 80 are easily attached/detached relative to each other by the bolts 90.

A vacuum exhaust system 94 and a gas supply system 96 for clean air or an inactive gas, such as N2 gas, are connected to the first buffer chamber 70. Namely, the first buffer chamber 70 has a so-called load-lock function to select a vacuum state and an atmospheric pressure state. Thus, the first buffer chamber 70 can intermediate between the vacuum atmosphere side and atmospheric pressure side (normal pressure side).

The entrance transfer chamber 32 always has a substantially atmospheric pressure (normal pressure) atmosphere therein. On the other hand, the middle transfer chamber 72, second buffer chamber 74, and common transfer chamber 36 always communicate with each other and have a vacuum atmosphere.

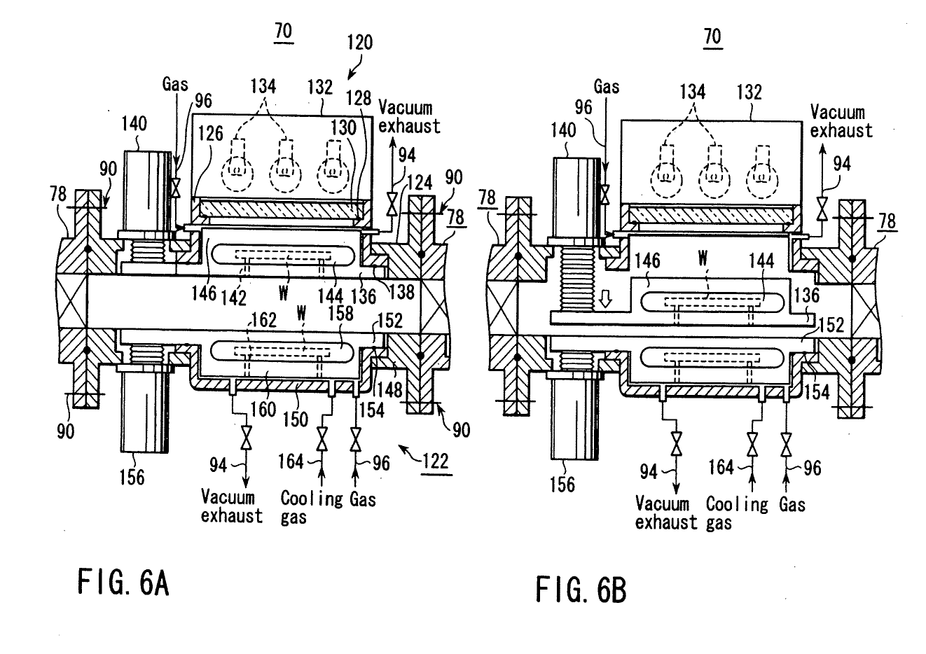

The first buffer chamber 70 has a structure the same as that disclosed in Jpn. Pat. Appln. KOKAI Publication No. 2000-299367. Specifically, as also shown in FIGS. 3, 6A and 6B, the first buffer chamber 70 includes a pre-heating mechanism 120 for pre-heating a wafer W, and a cooling mechanism 122 for cooling a wafer W. FIG. 6A shows a state where both of the pre-heating mechanism and cooling mechanism are in operation, while FIG. 6B shows a state where the upper switching lid 136 of the pre-heating mechanism is at a lower position.

More specifically, in the pre-heating mechanism 120, an opening is formed in the upper partition wall 124 of the first buffer chamber 70. An upper projecting receptacle 126 is attached to this opening in an airtight state and extends upward. The ceiling of the upper projecting receptacle 126 is opened, on which a transmission window 130 of, e.g., quartz is disposed airtightly by a sealing member 128, such as an O-ring. A casing 132 is placed above the transmission window 130, and a plurality of heating lamps 134 are disposed in the casing 132.

The upper switching lid 136 is disposed in the lower opening of the upper projecting receptacle 126 airtightly by a sealing member 138, such as an O-ring. More specifically, the upper switching lid 136 is supported on its one side to be movable up and down by an upper air cylinder 140, which is fixed to the upper partition wall 124. When the upper switching lid 136 is raised by the air cylinder 140, it closes the lower opening of the upper projecting receptacle 126 to form an airtight space therein, as shown in FIG. 6A.

A plurality of, e.g., three, support pins 142 (only two of them are illustrated) stand on the upper surface of the upper switching lid 136. The support pins 142 support a wafer W, while being in contact with the bottom of the wafer W. The upper switching lid 136 is provided with a reinforcing member 146 having an opened ceiling and sidewalls with two horizontally long transfer ports 144 (only one of them is illustrated in FIGS. 6A and 6B). A wafer W is transferred into and out of the upper switching lid 136 through the two transfer ports 144 in both of the left and right directions. In this illustrated example, one transfer port 144 is shown in the front side, for ease of understanding.

A vacuum exhaust system 94 connected to a vacuum pump (not shown), or the like, is connected to the sidewall of the upper projecting receptacle 126. The vacuum exhaust system 94 exhausts gas removed from the surface of a wafer in pre-heating the wafer (in a degas process). A supply system 96 for N2 gas or the like is also connected to the sidewall of the upper projecting receptacle 126.

On the other hand, in the cooling mechanism 122, an opening is formed in the lower partition wall 148 of the first buffer chamber 70. A lower projecting receptacle 150 is attached to this opening in an airtight state and extends downward. A lower switching lid 152 is disposed in the upper opening of the lower projecting receptacle 150 airtightly by a sealing member 154, such as an O-ring. More specifically, the lower switching lid 152 is supported on its one side to be movable up and down by a lower air cylinder 156, which is fixed to the lower partition wall 148. When the lower switching lid 152 is lowered by the air cylinder 156, it closes the upper opening of the lower projecting receptacle 150 to form an airtight space therein, as shown in FIG. 6A.

The lower switching lid 152 is provided with a reinforcing member 160 thereon, having sidewalls with two transfer ports 158 each having a long sideways shape. A wafer W is transferred into and out of the lower switching lid 152 through the two transfer ports 158 in both of the left and right directions. In this illustrated example, one transfer port 158 is shown in the front side, for ease of understanding. A plurality of, e.g., three, support pins 162 (only two of them are illustrated) stand on the upper surface of the bottom of the reinforcing member 160. The support pins 162 support a wafer W, while being in contact with the bottom of the wafer W.

A cooling gas system 164 for selectively feeding a cooling gas, such as cooled N2 gas, is connected to the bottom of the lower projecting receptacle 150. A vacuum exhaust system 94 connected to a vacuum pump (not shown), or the like, is also connected to the bottom of the lower projecting receptacle 150. This arrangement allows the cooling gas to be supplied and exhausted in cooling a wafer. A gas supply system 96 for supplying N2 gas or the like is also connected to the lower projecting receptacle 150.

The first buffer chamber 70 may be provided with only one of the cooling mechanism 122 and pre-heating mechanism 120. The interior of the first buffer chamber 70 may be arranged to be supplied with N2 gas and vacuum-exhausted as a whole. In this case, the upper switching lid 136 or lower switching lid 152 may be placed at the center, while gas is supplied by the gas supply system 96 and vacuum-exhausted by the vacuum exhaust system 94.

The middle transfer chamber 72 is provided with a middle transfer arm device 108 disposed therein, which is formed of an articulated arm device that can extend, contract, and rotate, and has one pick. The arm device 108 may have a plurality of, e.g., two, picks, so that it can handle a plurality of wafers at a time. An additional processing apparatus 110 (see FIG. 2) is connected to the sidewall of the middle transfer chamber 72 through a gate valve G1. The additional processing apparatus 110 is also provided with a gas supply system 111 and a vacuum exhaust system 113 in accordance a process to be performed. The additional processing apparatus 110 is set to perform a predetermined vacuum atmosphere process, such as cooling of a processed wafer, film thickness measurement of measuring a film thickness on a wafer, or particle measurement of measuring particles on a wafer, or an additional degas function, as needed.

As shown in FIG. 3, a wafer holder 116 is disposed in the second buffer chamber 74. The wafer holder 116 includes a base 112 and three struts standing thereon. The three struts have a plurality of, e.g., two wafer support grooves, so that it can support two wafers W at most at a time. The base 112 can rotate and move up and down by an elevating and rotating shaft 118, which airtightly penetrates the bottom of the second buffer chamber 74. The wafer holder 116 is arranged to hold two wafers, but the number of which does not set a limit thereto. The wafer holder 116 may be arranged to hold more that two wafers, or one wafer.

The base 112 of the wafer holder 116 is rotated to cause the notch or orientation flat of a wafer W to face in a predetermined direction relative to the arm device 46 disposed in the common transfer chamber 36. For example, where the vacuum processing apparatus 34A and the additional processing apparatus 110 on the left side in FIG. 1 are the same type of apparatus, the notch or orientation flat of a wafer W needs to be positioned at the same specific position (for example, a position on the transfer port side) in the apparatuses 34A and 110. In this case, if a wafer W is taken out of the apparatus 110 and only placed in the second buffer chamber 74 by the arm device 108 disposed in the middle transfer chamber 72, the notch or orientation flat of the wafer W is positioned on the side reverse to the side required by the apparatus 34A when the wafer W is transferred by the arm device 46 disposed in the common transfer chamber 36. The base 112 of the wafer holder 116 is rotated to solve this problem.

The second buffer chamber 74 may be provided with a vacuum exhaust system 94 and a gas supply system 96, as in the first buffer chamber 70. The entire arrangement described above is common to both of the transfer passages 38A and 38B.

An explanation will be give of an operation of the arrangement described above, according to this embodiment.

Prior to a process, the interior of the front side relative to the two first buffer chambers 70, i.e., of the entrance transfer chamber 32, in this example, is kept at atmospheric pressure (normal pressure). On the other hand, the deeper side relative to the two first buffer chambers 70, i.e., the two middle transfer chambers 72, two second buffer chambers 74, and common transfer chamber 36 communicate with each other and are kept at a vacuum atmosphere.

First, an unprocessed semiconductor wafer W is picked up by the arm device 58 disposed in the entrance transfer chamber 32, from a cassette container C placed on the table 52 in one of the three loading ports 54.

Then, the wafer W is transferred by the arm device 58 to the orientor 66, which then performs alignment of the wafer W.

Then, the wafer W aligned by the transfer arm device 58 is transferred into the first buffer chamber 70 of one of the two transfer passages 38A and 38B. In the first buffer chamber 70, the wafer W is held on the upper switching lid 136 of the pre-heating mechanism 120.

As described above, the first buffer chamber 70 has a load-lock function, degas function, and cooling function. The interior of the first buffer chamber 70 is vacuum-exhausted to a predetermined pressure by the vacuum exhaust system 94, in a state where the gate valves 78 on both sides of the first buffer chamber 70 accommodating the wafer W are airtightly closed. Then, the wafer W is heated by the heating lamp 134 or heating means, to perform a degas process.

After the degas process is performed for a predetermined time, as described above, and pressure adjustment is performed, the gate valve 78 on the middle transfer chamber 72 side is opened. The degas-processed wafer W is then transferred by the middle transfer arm device 108 from the first buffer chamber 70 onto the wafer holder 116 disposed in the second buffer chamber 74. The wafer holder 116 is rotated by a predetermined angle for angle adjustment, so that the notch or orientation flat of the wafer is directed to a predetermined direction for the next transfer.

Then, the wafer W is transferred by the common transfer arm device 46 disposed in the common transfer chamber 36, from the wafer holder 116 into a predetermined one of the four vacuum processing apparatuses 34A to 34D. Then, the wafer W is subjected to predetermined vacuum processes respectively in the vacuum processing apparatuses 34A to 34D. As regards these vacuum processes, the wafer W is sequentially transferred among the processing apparatuses 34A to 34D to receive different vacuum processes, as needed.

After all the vacuum processes on the wafer W are completed, as described above, the wafer W is transferred out though a course reverse to that described above. In this course, the wafer W is returned back to the middle transfer chamber 72, and transferred into the additional processing apparatus 110. The additional processing apparatus 110 is used to perform film thickness measurement, particle measurement, or the like, depending on the apparatus type. After the process or measurement on the wafer W is completed, the wafer W is transferred into the middle transfer chamber 72 again. Then, the wafer W is transferred into the first buffer chamber 70, which has been vacuum-exhausted to have a vacuum state, and is held on the support pins 162 on the lower switching lid 15 of the cooling mechanism 122. The wafer is cooled to a predetermined temperature by a cooling gas in the first buffer chamber 70, while maintaining an airtight state. After the cooling, pressure adjustment is performed here, and the wafer W is transferred through the entrance transfer chamber 32 to, e.g., the original cassette container C.

There is a case where the functions of the intermediate structures 37A and 37B including the transfer passages 38A and 38B need to be changed, after the processing system is installed in a factory. For example, the first buffer chamber 70 may need to be used as a simple passage with no degas function, or the additional processing apparatus 110 may need to be used for performing a process at an atmospheric pressure (normal pressure) atmosphere, such as wet washing or degassing, instead of a vacuum atmosphere process.

The conventional semiconductor processing system is designed without taking into consideration the need for a variable system structure, resulting in a unit structure in which almost all the parts are unchangeable. Accordingly, the requirement described above cannot be satisfied.

On the other hand, according to the semiconductor processing system shown in FIG. 1, the first and second buffer chambers 70 and 74, and the additional processing apparatus 110 are prepared as a module, as described above. These members 70, 74, and 110 are detachably connected to each other through the gate valve 78 and the sleeve pipe 80 with no valve function. The modules can be detached by unfastening the connection bolts 90 of the flanges, if another module needs to be combined therein. The gate valves 78 are at least disposed one on either side of a buffer chamber arranged to have a load-lock function for repeating vacuum-exhaust and return to atmospheric pressure in accordance with wafer transfer.

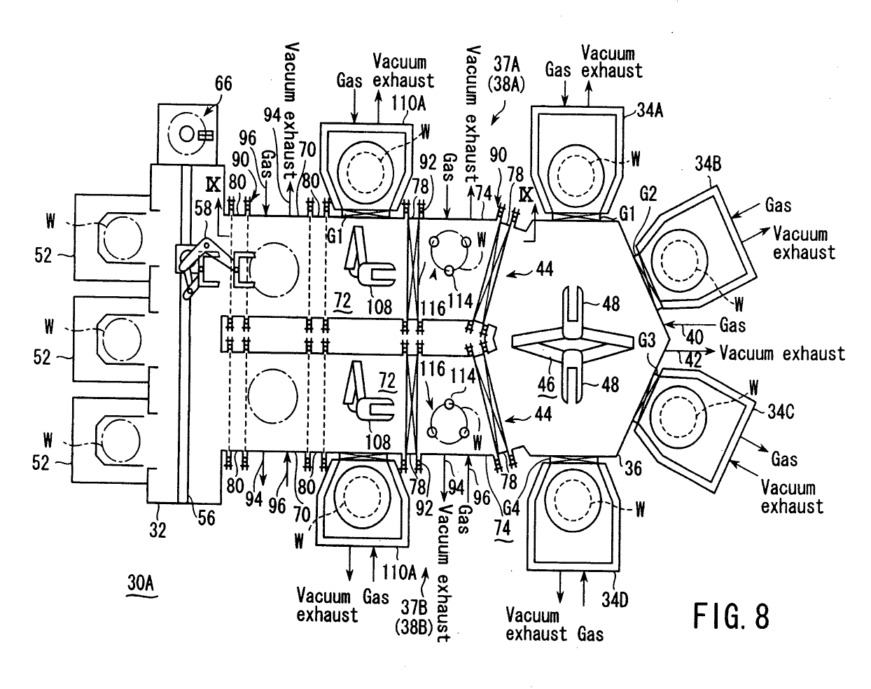

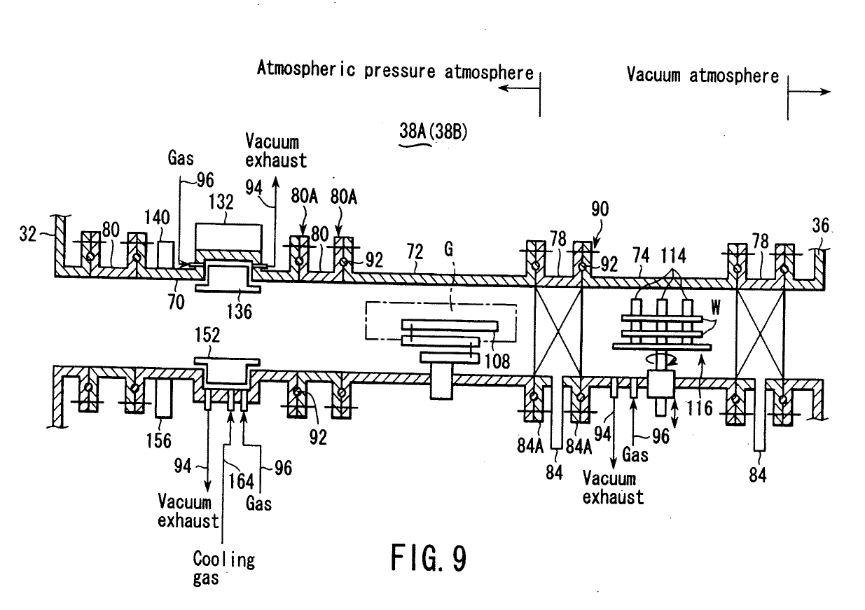

FIG. 7 is a schematic plan view showing another state of the processing system of FIG. 1, obtained by changing some modules. FIG. 8 is a plan view of the state of the processing system shown in FIG. 7. FIG. 9 is an enlarged sectional view taken along line IX-IX in FIG. 8.

This processing system 30A includes two second buffer chambers 74 set to be load-lock chambers. Each second buffer chamber 74 is connected to the adjacent chambers (the middle transfer chamber 72 and common transfer chamber 36) on both sides respectively through gate valves 78(see FIG. 4) in place of sleeve pipes 80 having no valve function (see FIG. 5). A vacuum exhaust system 94 and a gas supply system 96 are connected to the second buffer chamber 74, as in the first buffer chamber 70 shown in FIG. 2, so that the chamber 74 can be vacuum-exhausted. If the second buffer chamber 74 is provided with the vacuum exhaust system 94 and gas supply system 96 in advance, this module of the second buffer chamber 74 does not need to be replaced, and only requires the sleeve pipes 80 on both sides to be replaced with the gate valves 78.

The processing system in the state shown in FIG. 7 includes additional processing apparatuses 110A, each of which performs an atmospheric pressure atmosphere process, such as a degas process or wet washing process, as described above, instead of a vacuum atmosphere process. Accordingly, in the processing system 30A, each first buffer chamber 70 is provided with sleeve pipes 80 having no valve function on both sides, in place of gate valves 78. In the first buffer chamber 70, the support pins 142 on the upper switching lid 136 or the support pins 162 on the lower switching lid 152 are used only for temporarily holding a wafer W.

A module having an inner structure the same as that of the second buffer chamber 74 may be used as the first buffer chamber 70. Similarly, a module having an inner structure the same as that of the first buffer chamber 70 may be used as the second buffer chamber 74. In this case the second buffer chamber 74 has a cooling function or degas function.

In the processing system 30A, the entrance transfer chamber 32, two first buffer chambers 70, and two middle transfer chambers 72 always have an atmospheric pressure atmosphere therein. On the other than, the common transfer chamber 36 always has a vacuum atmosphere therein.

The processing system 30A may be modified, such that each middle transfer chamber 72 is provided with an inactive gas supply system and a vacuum exhaust system to keep its interior at an atmospheric pressure atmosphere with an inactive gas, such as N2 gas or Ar gas. In this case, gas replacement with N2 gas or Ar gas can be performed in each first buffer chamber 70, if it is provided with gate valves 78 on both sides, and also provided with an inactive gas supply system and a vacuum exhaust system.

In the states shown in FIGS. 1 and 7, the two intermediate structures 37A and 37B have interfaces between an atmospheric pressure atmosphere and a vacuum atmosphere, set at the same position. The two intermediate structures 37A and 37B may have interfaces between an atmospheric pressure atmosphere and a vacuum atmosphere, set at different positions.

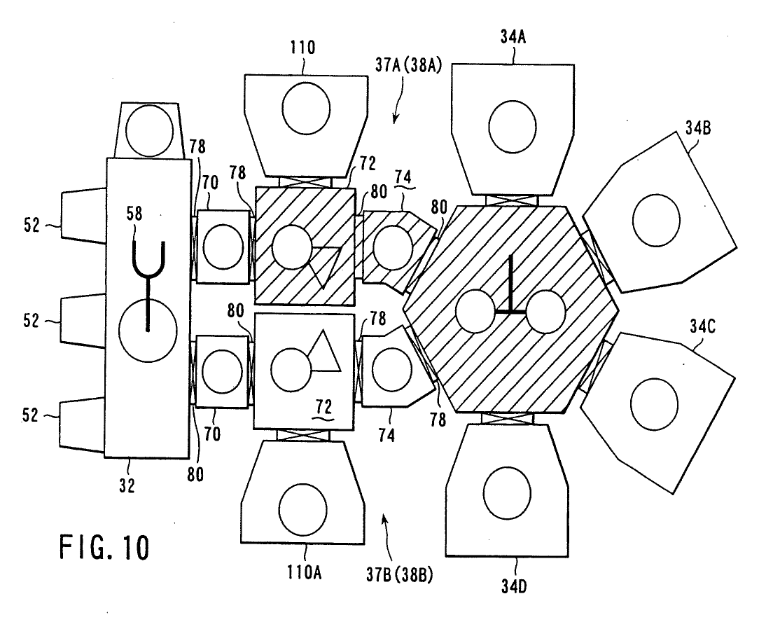

FIG. 10 is a schematic plan view showing still another state of the processing system of FIG. 1, obtained by changing some modules. In the state shown in FIG. 10, the intermediate structure 37A employs an additional processing apparatus 110 with a vacuum atmosphere, and thus includes a first buffer chamber 70 set to be a load-lock chamber. On the other hand, the intermediate structure 37B employs an additional processing apparatus 110A with an atmospheric pressure atmosphere, and thus includes a second buffer chamber 74 set to be a load-lock chamber.

Accordingly, as shown in FIGS. 1, 7, and 10, each of the intermediate structures 37A and 37B is selectively arranged to be in either of the following first and second states. In the first state, the additional processing apparatus 110 is set to perform a predetermined process on a wafer W within a vacuum atmosphere, while the first buffer chamber 70 is set to be a load-lock chamber for adjusting pressure between atmospheric pressure and vacuum. In the second state, the additional processing apparatus 110A is set to perform a predetermined process on a wafer W within an atmospheric pressure atmosphere, while the second buffer chamber 74 is set to be a load-lock chamber for adjusting pressure between atmospheric pressure and vacuum.

In the states shown in FIGS. 1, 7, and 10, any one of the first and second buffer chambers 70 and 74, which is not set to be a load-lock chamber, is connected to the adjacent chambers on both sides respectively through sleeve pipes 80 having no valve function. However, the chamber that is not set to be a load-lock chamber, of the first and second buffer chambers 70 and 74, may be connected to the adjacent chambers on both sides respectively through gate valves 78. In this case, the gate valves 78 of the chamber not set to be a load-lock chamber can be kept always open, under the control of software.

In a semiconductor processing system according to′, this embodiment of the present invention, each of the transfer passages 38A and 38B is formed of the first and second buffer chambers 70 and 74, and middle transfer chamber 72, which are prepared as modules and detachably connected to each other by gate valves 78 or sleeve pipes 80. Accordingly, after the processing system is installed in a factory, or when the processing system is manufactured before shipping, the system can comply with various applications. When the system application is changed, the buffer chambers are replaced with buffer chambers having other functions, while detaching the corresponding gate valves 78 or sleeve pipe 80. An area for maintaining a vacuum atmosphere can be easily and selectively changed by replacing the gate valves 78 with the sleeve pipes 80, and vice versa. Since each module can be easily attached and detached, maintenance thereof can be simplified.

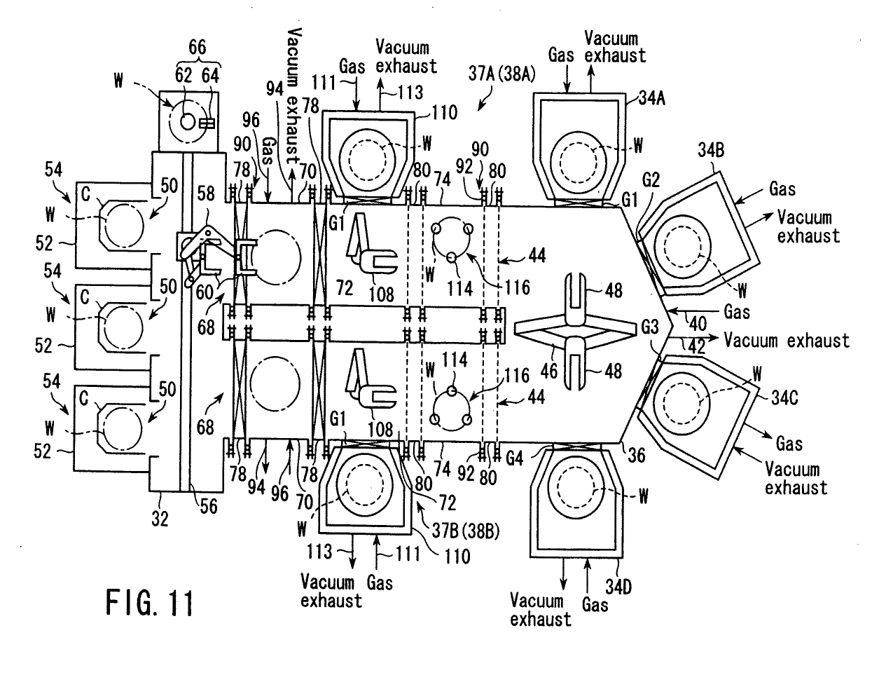

The common transfer chamber 36 of the system shown in FIGS. 1, 7, and 10 has an almost hexagonal shape, but it may have a rectangular, pentangular, heptangular, or higher order polygonal shape. FIG. 11 is a schematic plan view showing a semiconductor processing system according to another embodiment of the present invention, which has a pentangular common transfer chamber. In the system shown in FIG. 11, two second buffer chambers 74 are connected to one side of the common transfer chamber 36.

The system shown in FIGS. 1, 7, and 10 has the two intermediate structures 37A and 37B respectively defining the transfer passages 38A and 38B. However, the entrance transfer chamber 32 and common transfer chamber 36 may be connected only by an intermediate structure of one route, or by intermediate structures of three or more routes.

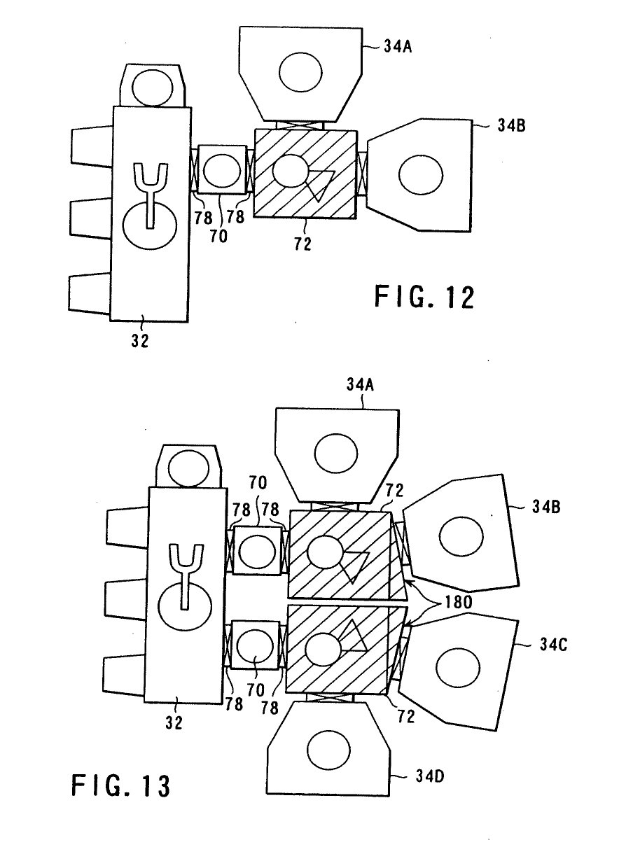

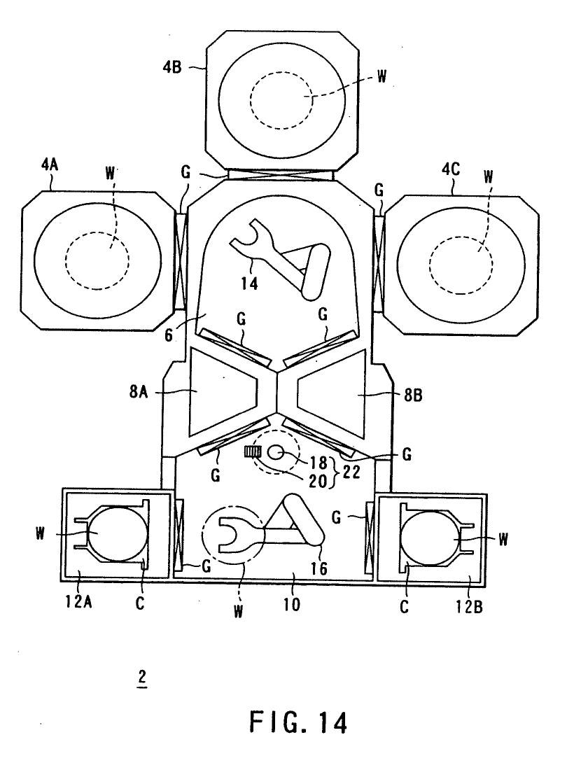

FIG. 12 is a schematic plan view showing a semiconductor processing system according to still another embodiment of the present invention. The system shown in FIG. 12 includes one route of a transfer passage formed of a first buffer chamber 70 and a middle transfer chamber 72, connected to an entrance transfer chamber 32. One or more processing apparatuses 34A and 34B are connected to the middle transfer chamber 72. As a result, a system arrangement is realized, similar to that disclosed in Jpn. Pat. Appln. KOKAI Publication No. 2000-208589.

FIG. 13 is a schematic plan view showing a semiconductor processing system according to still another embodiment of the present invention. The system shown in FIG. 13 includes a plurality of, two in this illustrated example, independent routes, each of which is a transfer passage formed of a first buffer chamber 70 and a middle transfer chamber 72, connected to an entrance transfer chamber 32. One or more processing apparatuses 34A and 34B are connected to each middle transfer chamber 72.

In the system shown in FIG. 13, the processing apparatuses 34B and 34C are connected to the middle transfer chamber 72 respectively through sleeve pipes (adapter) 180 having no valve function. Where the processing apparatuses 34B and 34C are large, they cannot be disposed without the sleeve pipes 180 that can change the connecting direction of the processing apparatuses relative to the middle transfer chamber 72. Each sleeve pipe 180 has the same structure as that of the sleeve pipe 80 show in FIG. 5 except that one attaching surface is inclined relative to the wafer transfer direction.

In the embodiments, a semiconductor wafer W is described as a target substrate. The present invention is not limited to this, and may be applied to a glass substrate or LCD substrate.

1. A semiconductor processing system comprising:
an entrance transfer chamber with an atmospheric pressure atmosphere set inside;
a common transfer chamber with a vacuum atmosphere set inside, which is connected to the entrance transfer chamber through an intermediate structure that forms a route for transferring a target substrate;
a plurality of vacuum processing apparatuses connected to the common transfer chamber, each of which is configured to perform a predetermined process on the target substrate within a vacuum atmosphere;
a first transfer arm device disposed in the entrance transfer chamber and configured to transfer the target substrate to and from the intermediate structure; and
a second transfer arm device disposed in the common transfer chamber and configured to transfer the target substrate between the intermediate structure and the vacuum processing apparatuses,
wherein the intermediate structure comprises
a transfer passage that connects the entrance transfer chamber and the common transfer chamber to allow the target substrate to pass therein, and includes a first buffer chamber, a middle transfer chamber, and a second buffer chamber connected in series in this order, such that the first and second buffer chambers are connected to the entrance transfer chamber and the common transfer chamber, respectively, wherein each of the first and second buffer chambers is connected to a gas supply system and a vacuum exhaust system, and at least one of the first and second buffer chambers is provided with gate valves respectively disposed on both sides and is configured to adjust inner pressure between atmospheric pressure and vacuum,
an additional processing apparatus connected to the middle transfer chamber, and
a third transfer arm device disposed in the middle transfer chamber and configured to transfer the target substrate between the first buffer chamber, the additional) processing apparatus, and the second buffer chamber.

2. The system according to claim 1, wherein at least one of the first and second buffer chambers has at least one of a degas function of performing a degas process by heating the target substrate and a cooling function of cooling the target substrate.

3. The system according to claim 1, wherein the entrance transfer chamber includes a loading port for loading the target substrate into the semiconductor processing system.

4. The system according to claim 1, wherein one of the first and second buffer chambers, which is not set to be a load-lock chamber, is provided with gate valves respectively disposed on both sides thereof, which are kept always open by software control.

5. The system according to claim 1, wherein the entrance transfer chamber and the first buffer chamber, the first buffer chamber and the middle transfer chamber, the middle transfer chamber and the second buffer chamber, and the second buffer chamber and the common transfer chamber are detachably connected by flanges.

6. The system according to claim 1, further comprising a rotary holder disposed in the second buffer chamber to rotate the target substrate by a predetermined angle.

7. A semiconductor processing system comprising:
an entrance transfer chamber with an atmospheric pressure atmosphere set inside;
a common transfer chamber with a vacuum atmosphere set inside, which is connected to the entrance transfer chamber through first and second intermediate structures that form routes parallel with each other for transferring the target substrate;
a plurality of vacuum processing apparatuses connected to the common transfer chamber, each of which is configured to perform a predetermined process on the target substrate within a vacuum atmosphere;
a first transfer arm device disposed in the entrance transfer chamber and configured to transfer the target substrate to and from the first and second intermediate structures; and
a second transfer arm device disposed in the common transfer chamber and configured to transfer the target substrate between the intermediate structure and the vacuum processing apparatuses,
wherein each of the first and second intermediate structures comprises
a transfer passage that connects the entrance transfer chamber and the common transfer chamber to allow the target substrate to pass therein, and includes a first buffer chamber, a middle transfer chamber, and a second buffer chamber connected in series in this order, such that the first and second buffer chambers are connected to the entrance transfer chamber and the common transfer chamber, respectively,
an additional processing apparatus connected to the middle transfer chamber, and
a third transfer arm device disposed in the middle transfer chamber and configured to transfer the target substrate between the first buffer chamber, the additional processing apparatus, and the second buffer chamber,
wherein the first buffer chamber of the first intermediate structure is connected to a gas supply system and a vacuum exhaust system, is provided with gate valves respectively disposed on both sides, and is configured to adjust inner pressure between atmospheric pressure and vacuum, while the middle transfer chamber of the first intermediate structure has a vacuum atmosphere set inside, and
wherein the second buffer chamber of the second intermediate structure is connected to a gas supply system and a vacuum exhaust system, is provided with gate valves respectively disposed on both sides, and is configured to adjust inner pressure between atmospheric pressure and vacuum, while the middle transfer chamber of the second intermediate structure has an atmospheric pressure atmosphere set inside.

8. The system according to claim 7, wherein at least one of the first buffer chamber of the first intermediate structure and the second buffer chamber of the second intermediate structure has at least one of a degas function of performing a degas process by heating the target substrate and a cooling function of cooling the target substrate.

9. The system according to claim 7, wherein the entrance transfer chamber includes a loading port for loading the target substrate into the semiconductor processing system.

10. The system according to claim 7, wherein each of the second buffer chamber of the first intermediate structure and the first buffer chamber of the second intermediate structure is provided with gate valves respectively disposed on both sides, which are kept always open by software control.

11. The system according to claim 7, wherein the entrance transfer chamber and the first buffer chamber, the first buffer chamber and the middle transfer chamber, the middle transfer chamber and the second buffer chamber, and the second buffer chamber and the common transfer chamber are detachably connected by flanges.

12. The system according to claim 7, further comprising a rotary holder disposed in the second buffer chamber to rotate the target substrate by a predetermined angle.

13. A semiconductor processing system comprising:
an entrance transfer chamber with an atmospheric pressure atmosphere, which has a loading port for loading a target substrate into the semiconductor processing system;
a common transfer chamber with a vacuum atmosphere, which is connected to the entrance transfer chamber through an intermediate structure that forms a route for transferring the target substrate;
a plurality of vacuum processing apparatuses connected to the common transfer chamber, each of which is configured to perform a predetermined process on the target substrate within a vacuum atmosphere;
a transfer arm device disposed in the entrance transfer chamber and configured to transfer the target substrate between a portion outside the semiconductor processing system and the intermediate structure; and
a transfer arm device disposed in the common transfer chamber and configured to transfer the target substrate between the intermediate structure and the vacuum processing apparatuses,
wherein the intermediate structure comprises
a transfer passage that connects the entrance transfer chamber and the common transfer chamber to allow the target substrate to pass therein, and includes a first buffer chamber, a middle transfer chamber, and a second buffer chamber connected in series in this order and detachable from each other, such that the first and second buffer chambers are detachably connected to the entrance transfer chamber and the common transfer chamber, respectively,
an additional processing apparatus detachably connected to the middle transfer chamber, and
a transfer arm device disposed in the middle transfer chamber and configured to transfer the target substrate between the first buffer chamber, the additional processing apparatus, and the second buffer chamber; and
the intermediate structure is selectively arranged to be in one of first and second states, the first state being a state where the additional processing apparatus is set to perform a predetermined process on the target substrate within a vacuum atmosphere, while the first buffer chamber is set to be a load-lock chamber for adjusting pressure between atmospheric pressure and vacuum, and the second state being a state where the additional processing apparatus is set to perform a predetermined process on the target substrate within an atmospheric pressure atmosphere, while the second buffer chamber is set to be a load-lock chamber for adjusting pressure between atmospheric pressure and vacuum,
wherein one of the first and second buffer chambers, which is set to be the load-lock chamber, is connected to adjacent chambers on both sides respectively through gate valves, and one of the first and second buffer chambers, which is not set to be the load-lock chamber, is connected to adjacent chambers on both sides respectively through sleeve pipes having no valve function.

14. The system according to claim 13, wherein the entrance transfer chamber and the first buffer chamber, the first buffer chamber and the middle transfer chamber, the middle transfer chamber and the second buffer chamber, and the second buffer chamber and the common transfer chamber are detachably connected by flanges.

15. The system according to claim 13, wherein one of the first and second buffer chambers, which is set to be the load-lock chamber, has a degas function of performing a degas process by heating the target substrate, and/or a cooling function of cooling the target substrate.

16. The system according to claim 13, further comprising a rotary holder disposed in the second buffer chamber to rotate the target substrate by a predetermined angle.

17. A semiconductor processing system comprising:
an entrance transfer chamber with an atmospheric pressure atmosphere, which has a loading port for loading a target substrate into the semiconductor processing system;
a common transfer chamber with a vacuum atmosphere, which is connected to the entrance transfer chamber through first and second intermediate structures that form routes parallel with each other for transferring the target substrate;
a plurality of vacuum processing apparatuses connected to the common transfer chamber, each of which is configured to perform a predetermined process on the target substrate within a vacuum atmosphere;
a transfer arm device disposed in the entrance transfer chamber and configured to transfer the target substrate between a portion outside the semiconductor processing system and the first and second intermediate structures; and
a transfer arm device disposed in the common transfer chamber and configured to transfer the target substrate between the first and second intermediate structures and the vacuum processing apparatuses,
wherein each of the first and second intermediate structures comprises
a transfer passage that connects the entrance transfer chamber and the common transfer chamber to allow the target substrate to pass therein, and includes a first buffer chamber, a middle transfer chamber, and a second buffer chamber connected in series in this order and detachable from each other, such that the first and second buffer chambers are detachably connected to the entrance transfer chamber and the common transfer chamber, respectively,
an additional processing apparatus detachably connected to the middle transfer chamber, and
a transfer arm device disposed in the middle transfer chamber and configured to transfer the target substrate between the first buffer chamber, the additional processing apparatus, and the second buffer chamber,
wherein each of the first and second intermediate structures is selectively arranged to be in one of first and second states, the first state being a state where the additional processing apparatus is set to perform a predetermined process on the target substrate within a vacuum atmosphere, while the first buffer chamber is set to be a load-lock chamber for adjusting pressure between atmospheric pressure and vacuum, and the second state being a state where the additional processing apparatus is set to perform a predetermined process on the target substrate within an atmospheric pressure atmosphere, while the second buffer chamber is set to be a load-lock chamber for adjusting pressure between atmospheric pressure and vacuum, and
wherein, in each of the first and second intermediate structures, one of the first and second buffer chambers, which is set to be the load-lock chamber, is connected to adjacent chambers on both sides respectively through gate valves, and one of the first and second buffer chambers, which is not set to be the load-lock chamber, is connected to adjacent chambers on both sides respectively through sleeve pipes having no valve function.

18. The system according to claim 17, wherein the first and second intermediate structures are set to be states different from each other, selected from the first and second states.

19. The system according to claim 17, wherein the first and second intermediate structures are set to be in states which are the same as each other, selected from the first and second states.

20. The system according to claim 17, wherein, in each of the first and second intermediate structures, the entrance transfer chamber and the first buffer chamber, the first buffer chamber and the middle transfer chamber, the middle transfer chamber and the second buffer chamber, and the second buffer chamber and the common transfer chamber are detachably connected by flanges.
